(19) United States
(12) Patent Application Publication
(10) Pub. No.: US 2025/0037972 A1
(43) Pub. Date: Jan. 30, 2025

(54) MATCH NETWORK DESIGN FOR USE WITH FREQUENCY SWEEPING

(71) Applicant: Advanced Energy Industries, Inc., Denver, CO (US)

(72) Inventor: Masahiro Watanabe, Windsor, CO (US)

(21) Appl. No.: 18/359,840

(22) Filed: Jul. 26, 2023

(51) Int. Cl. H01J 37/32; H03H 7/40

(52) U.S. Cl. CPC H01J 37/32183; H03H 7/40; H01J 2237/327

(57) ABSTRACT

Match networks, systems, and methods are disclosed. A match network comprises an input, an output, a first variable reactive component, a second variable reactive component, a third variable reactive component, and a controller. The controller is configured to control the first variable reactive component and the second variable reactive component to, at least in part, match a load impedance at the output to a source impedance at the input during a first and second states, and the controller is configured to set the third variable reactive component so that frequency sweeping completes tuning during at least one of the states.

### BACKGROUND

### Field

The present disclosure relates generally to plasma processing systems, and more specifically, to impedance matching in plasma processing systems.

### Background

In plasma processing, generators are used to supply power to a plasma load. Today's advanced plasma processes include ever more complicated recipes and recipe-changing procedures in which the plasma load impedance dynamically changes. This can make it challenging to match the source impedance of the generator with the plasma load for efficient power transfer. Such impedance matching can be performed using a match network, but this approach is relatively slow in the context of modern short-duration plasma processes. An alternative approach is to adjust the frequency of the generator, which alters the impedance of the load present to the generator. In this context, the load presented to the generator includes the plasma itself, components associated with a plasma processing chamber, and any match network.

Although match tuning and frequency tuning are known approaches to impedance tuning, current match networks are often unable to provide impedance matching in the context of multi-state power application that is often utilized in today's plasma processing systems.

### SUMMARY

According to an aspect, a match network comprises an input, an output, a first variable reactive component, a second variable reactive component, a third variable reactive component, and a controller. The controller is configured to control the first variable reactive component and the second variable reactive component to, at least in part, match a load impedance at the output to a source impedance at the input during a first and second states, and the controller is configured to set the third variable reactive component so that frequency sweeping completes tuning during at least one of the states.

According to another aspect, a method is disclosed where the method includes providing power to a dynamic load impedance, matching a source impedance to the dynamic load impedance during a first and second impedance states by, at least in part, adjusting a first variable reactive component and a second variable reactive component of a match network, and setting a third variable reactive component of the match network so that frequency sweeping completes tuning during at least one of the first and second impedance states.

According to yet another aspect, a non-transitory processor-readable medium is disclosed that comprises instructions for matching a source impedance with a dynamic load impedance, for execution by a processor or for configuring a field programmable gate array. The instructions comprise instructions to match a source impedance to the dynamic load impedance during a first and second impedance states by, at least in part, adjusting a first variable reactive component and a second variable reactive component of a match network, and the instructions comprise instructions to set a third variable reactive component of the match network so that frequency sweeping completes tuning during at least one of the impedance states.

### BRIEF DESCRIPTION OF THE DRAWINGS

FIG. 1 is a block diagram of a plasma processing system in accordance with an embodiment of this disclosure;

FIG. 2 is a graph depicting examples of different power states that may be applied to a plasma processing chamber;

FIG. 3A is a graph depicting examples of load impedance for two different power states;

FIG. 3B is a graph depicting an effect of sweeping frequency;

FIG. 4 is a flowchart representing a method that may be traversed in connection with embodiments of this disclosure;

FIG. 5 is a schematic depiction of an example variable reactance section;

FIG. 6A is a graph depicting an effect of a value for the third capacitance during frequency sweeping;

FIG. 6B is a graph depicting an effect of another value for the third capacitance during frequency sweeping;

FIG. 6C is a graph depicting an effect of yet another value for the third capacitance during frequency sweeping;

FIG. 7 is a block diagram depicting physical components that may be used to implement an element controller in accordance with an embodiment of this disclosure.

### DETAILED DESCRIPTION

The following modes, features or aspects, given by way of example only, are described in order to provide a more precise understanding of the subject matter of several embodiments.

The word “exemplary” is used herein to mean “serving as an example, instance, or illustration.” Any embodiment described herein as “exemplary” is not necessarily to be construed as preferred or advantageous over other embodiments.

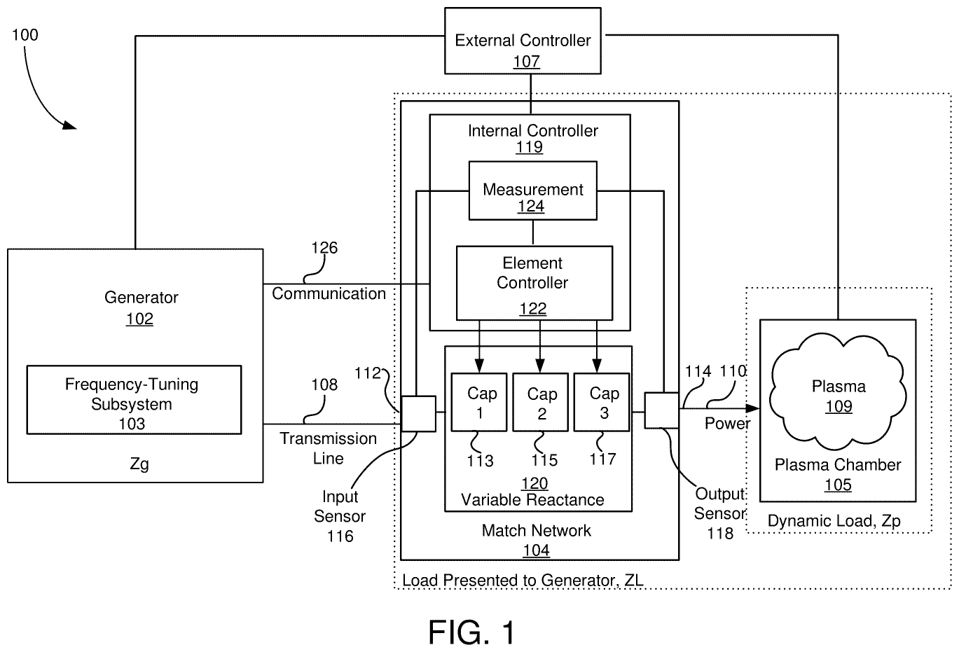

Referring first to FIG. 1, shown is a plasma processing system 100 including a generator 102, match network 104, a plasma chamber 105, and an external controller 107. In operation, the generator 102 applies power (e.g., medium frequency power, radio frequency (RF) power, or power at any frequency where impedance matching is beneficial) to the match network 104 via a transmission line 108 (e.g., coaxial cable) and then onto the plasma chamber 105 via an electrical connection 110. In this embodiment, the generator 102 includes a frequency-tuning subsystem 103 that is configured to adjust a frequency of the generator 102.

The match network 104 includes an input 112 including an electrical connector (not shown) to couple to the generator 102 via the transmission line 108 and an output 114 including an electrical connector (not shown) to couple to the plasma chamber 105 via the electrical connection 110. As shown, the match network 104 also includes an input sensor 116 and an output sensor 118 that are both coupled to an internal controller 119, which includes a measurement section 124, an element controller 122, and a variable reactance section 120.

In general, the match network 104 functions to transform an impedance at the output 114 of the match network 104 to a desired impedance value (that is presented to the transmission line 108 at an input 112 of the match network 104). As discussed further herein, the match network 104 may function in connection with the frequency-tuning subsystem 103 to transform an impedance at the output 114 of the match network 104 to a desired impedance value for the load, ZL (that is presented to the transmission line 108 at an input 112 of the match network 104). For example, the internal controller 119 may monitor a reflection coefficient, and the internal controller 119 may adjust the variable reactive components 113, 115, 117, in view of the frequency-sweeping capability of the generator 102, to achieve a desired impedance value (or potential impedance values) across multiple power states. As used herein, “reactive component” refers to a capacitance or inductance where the capacitance includes one or more capacitors, and the inductance includes one or more inductors.

The desired value for the impedance presented to the generator 102 may be a complex conjugate of the source impedance, Zg, of the generator 102 (to provide complex conjugate matching), or the desired value for the impedance of the load, ZL may intentionally be offset from the source impedance, Zg, of the generator 102. As described in more detail further herein, the algorithm carried out by the element controller 122 of the match network 104 may be designed with the assumption that the frequency-tuning subsystem 103 of the generator 102 will operate to adjust the frequency of the generator 102 when the generator 102 sees an impedance at the transmission line 108 that is not the desired value for the impedance of the dynamic load, Zp. In other words, in many implementations, the match network 104 is designed and configured to complement the operation of the frequency-tuning subsystem 103.

It is contemplated that the match network 104 may be configured to operate to substantially minimize reflected power or the match network 104 may be configured to minimize another operational parameter such an instability parameter. Along these lines, the desired value for the impedance of the load, ZL may be matched to the source impedance, Zg, of the generator 102 (e.g., complex conjugate matched) or offset from the source impedance, Zg, of the generator 102.

Regardless of whether the desired value for the impedance of the load, ZL is matched to the source impedance, Zg, of the generator 102 (e.g., complex conjugate matched) or offset from the source impedance, Zg, of the generator 102, the third variable reactive component 117 functions to enable frequency tuning (by sweeping a output frequency of the generator(s)) to achieve the desired value. More specifically, the element controller 122 of the match network 104 is configured to: control the first variable reactive component 113 and second variable reactive component 115 to, at least in part, match a dynamic load, Zp, to a source impedance, Zg, at the input 112 during a first and second states and the element controller 122 sets the third variable reactive component 117 so that frequency sweeping (performed by the frequency-tuning subsystem 103) completes tuning during at least one of the states.

As discussed further herein, the frequency-tuning subsystem 103 may receive measurements indicative of an impedance of the dynamic load, Zp (e.g., measurements indicative of reflected power) from one or more sensors and the frequency-tuning subsystem 103 processes those measurements to produce frequency adjustments in the generator 102.

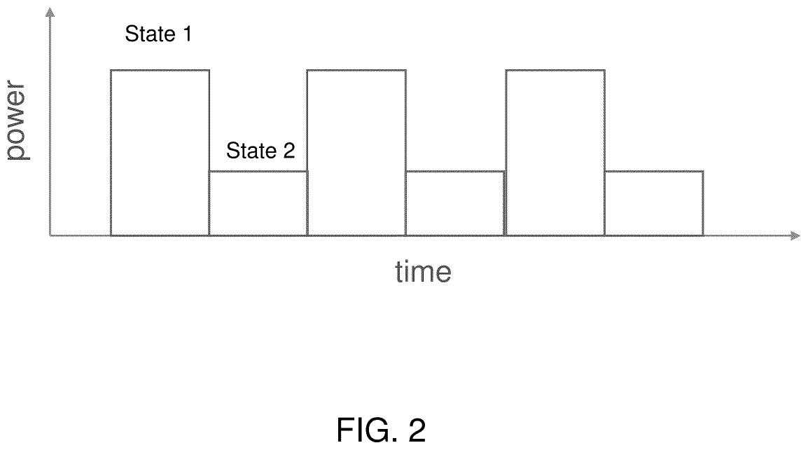

The generator 102 may be realized by a variety of different types of generators that may operate at a variety of different power levels and frequencies. In some modes of operation, the generator 102 operates to provide different operational states as a function of time. Referring briefly to FIG. 2 for example, the generator 102 may operate to apply multi-level pulsing to the plasma chamber 105. As shown in FIG. 2, State 1 may be the application of power at a first power level and State 2 may be the application of power at a second power level. It should be recognized that FIG. 2 is only an example of the type of different power states that may be utilized in connection with dual-level plasma processing. More specifically, there may be more than two different states, and the states may differ in terms of the frequency of power (instead of amplitude of power) that is provided during each state. It is also contemplated that both power and frequency may change from state to state.

It should also be recognized that two or more generators may be coupled to the match network 104. As described further herein, in some implementations of the plasma processing system 100, generator 102 may generally operate around a frequency of 13.56 MHz and another generator coupled to the match network may generally operate at 40 MHz. For example, generator 102 may operate at 13.56 MHz during State 1 and another generator may operate at 40 MHz during State 2. The external controller 107 may control the two generators so that the generator 102 operates during some processing steps and the other generator(s) operate during other processing steps. These frequencies are merely examples and other frequencies may be used by the generator(s).

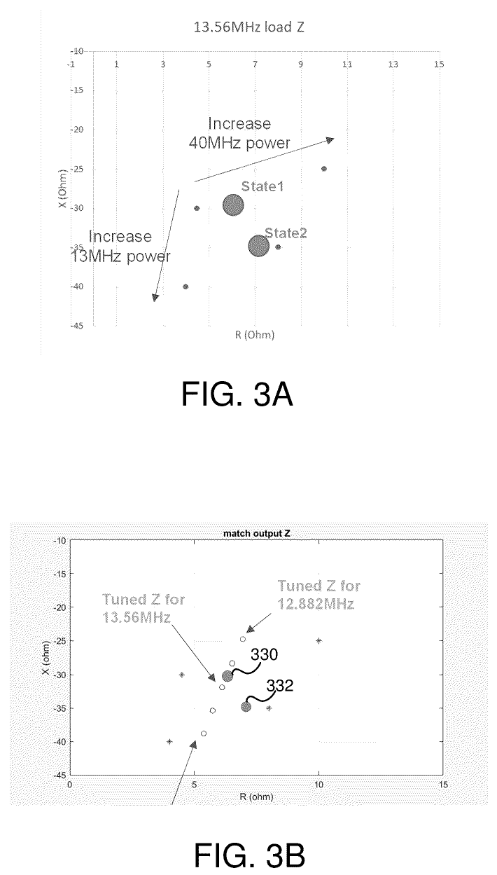

The use of two or more power states in plasma processing can make it difficult to achieve impedance matching. Referring to FIG. 3A for example, shown is a graph depicting an example of where the load impedance may be for State 1 and State 2. Also shown in FIG. 3A are directions the load impedance will move for increasing 13.56 MHz power and for increasing 40 MHz power.

One approach to impedance matching includes utilizing the match network 104 to carry out “match tuning” during State 1 or State 2 while using frequency tuning during the other state. For example, match tuning may be used during a primary state and frequency tuning may be used during one or more secondary state(s). This approach is attractive because match networks are often too slow to tune state by state and frequency tuning is very quick. But problematically, as shown in FIG. 3A, the direction of load impedance becomes two dimensional, and as shown in FIG. 3B, frequency tuning may be substantially one dimensional. More specifically, FIG. 3B depicts the output impedance of a typical match network, with an “L” topology,” across a range of frequencies from 12.882 MHz to 14.238 MHz. As shown, the output impedance of a typical match network may be tuned, by match tuning, to provide a desired first-state-match-output-impedance 330, but frequency tuning alone (without adjusting the match network) in connection with a typical match will not move the match output impedance to a desired second-state-match-output-impedance 332. As a consequence, a typical match network does not enable quick impedance tuning from one power state to another.

To address this problem, in addition to a first variable reactive component 113 and a second variable reactive component 115, the variable reactance section 120 of the match network 104 includes a third variable reactive component 117 that may be set so that frequency tuning may complete the process of impedance tuning. It should be recognized that each of the first variable reactive component 113, the second variable reactive component 115, and the third variable reactive component 117 represent one or more reactive components. For example, one or more of the variable reactive components may be realized by one or more variable vacuum capacitors or one or more variable inductors. As another example, one or more of the variable reactive components may be realized by an array of fixed capacitors or an array of fixed inductors where each capacitor or inductor may be combined with a switch (e.g., a PIN diode) so that each reactive component is switchably engaged and disengaged to select a capacitance or inductance. And the arrangement of the reactive components of the variable reactance section 120 may be consistent with known match architectures. For example, without limitation, the variable reactance section 120 may be arranged in a “π,” “T,” “L.” or other type of architecture.

Regardless of the type of architecture that is utilized, those of ordinary skill in the art will appreciate (in view of this disclosure) that the first variable reactive component 113 may comprise one or more tuning elements that primarily affect the real part of the impedance presented to the generator 102. In some architectures, the first variable reactive component 113 comprises one or more shunt elements (e.g., one or more shunt capacitors). In some architectures, the second variable reactive component 115 comprises one or more series capacitors that primarily affect the imaginary part of the impedance presented to the generator 102.

The third variable reactive component 117 may be a shunt capacitor or a series capacitor that is set to a capacitance to achieve a desired impedance trajectory when the generator 102 performs frequency sweeping. For example, the first variable reactive component 113 and the second variable reactive component 115 may be controlled so that, at least in part, the load impedance at the output 114 is matched to a source impedance at the input 112 during a first and second states and the third variable capacitor may be set so that frequency sweeping completes tuning during at least one of the states.

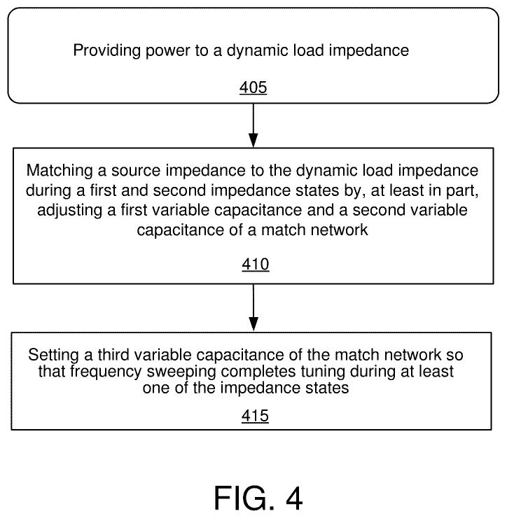

Referring briefly to FIG. 4, shown is a flowchart depicting a method that may be traversed in connection with embodiments disclosed herein. As shown, power is provided to the dynamic load impedance, Zp (Block 405) and the source impedance of the generator 102 is matched to the dynamic load impedance, Zp, during a first and second impedance states by, at least in part, adjusting the first variable reactive component 113 and the second variable reactive component 115 of the match network 104 (Block 410). A third variable reactive component 117 of the match network is set so that frequency sweeping completes tuning during at least one of the impedance states (Block 415).

As a specific example, the first variable reactive component 113 and the second variable reactive component 115 may be used to substantially match the dynamic load impedance, Zp, to the source impedance of the generator 102 during a first impedance state and the third variable reactive component 117 may be set so that frequency tuning completes tuning during the second state.

As another example, the first variable reactive component 113 and the second variable reactive component 115 and frequency tuning may be used to substantially match the dynamic load impedance, Zp, to the source impedance of the generator 102 during a first impedance state and the first variable reactive component 113 and the second variable reactive component 115 may be set to partially match dynamic load impedance, Zp, to the source impedance of the generator 102 during the second state while the third variable reactive component 117 may be set so that frequency tuning completes tuning during the second state.

One way to set the third variable reactive component 113 at Block 415 is to preset positions for the third variable reactive component 113. Another way, is a more comprehensive tuning algorithm which utilizes all three variable reactive components and frequency together, and the best variable reactive component positions and frequency are predicted together. One single algorithm may be effectuated by software/firmware located either inside the match network 104 or the generator 102 (or an external controller 107 system).

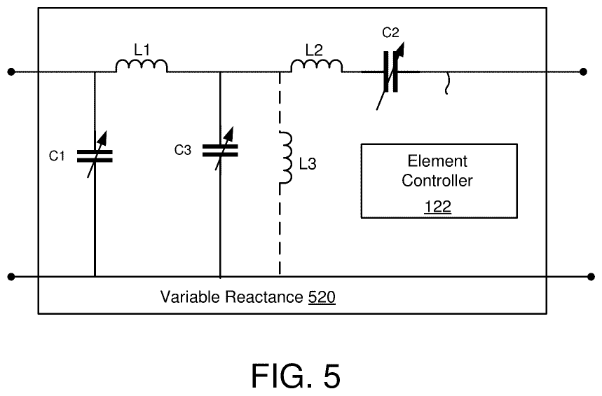

Referring briefly to FIG. 5, shown is a variable reactance section 520 that is an example of the variable reactance section 120 of FIG. 1. It should be recognized that the topology depicted in FIG. 5 is only an example and that other topologies may be utilized. In the variable reactance section 520, a first capacitance, C1, second capacitance, C2, and third capacitance, C3, are examples of the first variable reactive component 113, the second variable reactive component 115, and the third variable reactive component 117, respectively. As shown, the first capacitance (shunt element, C1) is disposed across transmission lines of the match network 104 and the second capacitance (a series element, C2) is disposed in series along one of the transmission lines. Each of the shunt element, C1, and the series element, C2, and third capacitance, C3 may be coupled to the element controller 122 by control lines to enable the element controller 122 to adjust each of the variable capacitances.

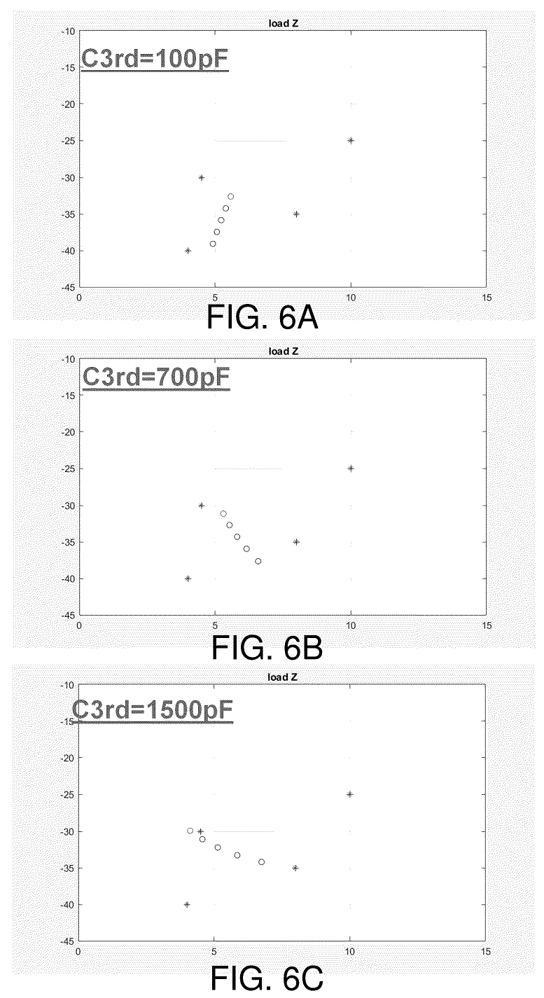

Referring briefly to FIGS. 6A, 6B, and 6C, shown are graphs depicting examples of load impedance, ZL, presented to the generator 102 that result from changing a capacitance value of the third capacitance, C3. As shown, in FIG. 6A when the capacitance value of the third capacitance, C3, is 100 pF, the trajectory of the load impedance is generally one dimensional so that sweeping the frequency of the generator 102 (e.g., from 12.882 MHZ to 14.238 MHz) results in very little change to the real part of the load impedance, ZL, presented to the generator 102. When the value of the third capacitance, C3, is increased to 750 pF, frequency sweeping of the generator 102 (e.g., from 12.882 MHz to 14.238 MHz) results in a greater displacement (relative to frequency sweeping when C3 is 100 pF) of the real part of the load impedance, ZL, presented to the generator 102. And as shown in FIG. 6C, increasing the capacitance of the third capacitance, C3, to 1500 pF results in yet an even greater displacement (relative to frequency sweeping when C3 is 100 pF or 750 pF) of the real part of the load impedance, ZL, presented to the generator 102. As shown in FIG. 6C, setting the value of the third variable reactive component 117 enables frequency tuning to be used to complete impedance tuning during any impedance state.

And in one use case, the element controller 122 is configured to control the first capacitance, C1, and second capacitance, C2, together to match the dynamic load impedance, Zp, at the output 114 of the match network to a source impedance of the generator 102 seen at the input 112 of the match network during a first impedance state, and the third capacitance, C3, value may be set so that the that frequency tuning (carried out by the frequency-tuning subsystem 103 of the generator completes tuning during a second impedance state. Referring again to FIG. 3A, match tuning (by adjusting the first variable reactive component 113 and the second variable reactive component 115) may be used for State 1, and by virtue of the impedance trajectory provided by the third reactive component 117, frequency tuning may be used for State 2.

Although not shown to keep the depiction of FIG. 1 simple and clear, one of ordinary skill in the art will readily appreciate that the generator 102, the match network 104, and/or the external controller 107 may include a user interface to enable an operator of the plasma processing system 100 to control and monitor the plasma processing system 100. It should also be noted that the depiction of the external controller 107 should not be construed to mean that common supervisory control over the generator 102 and match network 104 is required.

The plasma 109 may be a plasma formed in the plasma chamber 105, which is known for performing processing such as the etching of substrates or the deposition of thin layers upon substrates. The plasma 109 is typically achieved by the formation of plasmas within low pressure gases. The plasma is initiated and sustained by the generator 102 (and potentially additional generators), and the match network 104 is employed to ensure the generator 102 sees a desired impedance (typically, although not always, 50 ohms) at the output of the generator 102. As shown, the impedance presented to the generator 102 by the load, ZL, includes the plasma 109 itself, components associated with a plasma chamber 105, and the match network 104.

The generator 102 may apply power to the plasma chamber 105 by a conventional 13.56 MHz signal, but as discussed, other frequencies may also be utilized. The generator 102 may have a source impedance, Zg, of 50 ohms and an output stage to match the source impedance of the generator 102 to the impedance of the transmission line 108, which may be a typical transmission line (such as a 50 ohm coaxial cable). The source impedance of the generator, Zg, may be 50 ohms, but those of ordinary skill in the art of plasma processing systems will appreciate that, depending upon the particular type (e.g., design architecture, make, and/or model) of generator used to realize the generator 102, the source impedance, Zg, of the generator 102 may differ from 50 ohms.

The external controller 107 may be realized by hardware or hardware in connection with software, and the external controller 107 may be coupled to several components of a plasma processing system 100 including the generator 102, match network 104, equipment coupled to the plasma chamber 105, other generators, mass flow controllers, etc.

It should be recognized that the values of power-related parameters referred to herein (e.g., voltage, current, impedance, forward power, reflected power, and delivered power) are generally complex numbers that may be represented in terms of a real part and an imaginary part. Impedance, Z, for example may be represented in terms of resistance “R” (real part) and reactance “X” (imaginary part): Z=R+Xj where j is the square root of negative 1.

The measurement section 124 may receive signals from the input sensor 116 and/or the output sensor 118 that are indicative of electrical parameter values at the input 112 and/or the output 114 of the match network 104. In turn, the measurement section 124 may provide one or more processed signals to the element controller 122, which controls settings of the first variable reactive component 113, second variable reactive component 115, and third variable reactive component 117. such that the input impedance of the match network 104 is adjusted.

The input sensor 116 and/or the output sensor 118 may be realized by a conventional dual directional coupler (known to those of ordinary skill in the art) that includes sensing circuitry that provides outputs indicative of forward and reflected power at the input of the match network 104. The input sensor 116 and/or the output sensor 118 may also be realized by a conventional voltage-current (V/I) sensor (known to those of ordinary skill in the art) that includes sensing circuitry that provides outputs indicative of voltage, current, and a phase between the voltage and current. As a nonlimiting example, a directional coupler may be used to realize the input sensor 116 and a V/I sensor may be used to realize the output sensor 118. The input sensor 116 and/or the output sensor 118 may also comprise a frequency sensor known to those of ordinary skill in the art. Moreover, each of the input and output sensors 116, 118 may be realized by more than one separate sensors (e.g., a separate voltage sensor and a separate current transducer). In other words, although a single block is depicted for each of the input sensor 116 and output sensor 118, the single blocks each represent one or more sensors (and potentially processing circuitry).

The measurement section 124 may include processing components to sample, filter, and digitize the outputs of the input sensor 116 for utilization by the element controller 122. It is also contemplated that signals from the output sensor 118 may be utilized to control the variable reactance section 120. In any event, as discussed further herein, the element controller 122 may adjust the variable reactance section 120 to present an impedance to the transmission line 108 (and hence the generator 102) that is mismatched while the frequency of the generator 102 is at a frequency other than the target frequency. In this way, the frequency-tuning subsystem 103 of the generator 102 may simultaneously adjust the frequency of the generator 102 to both, arrive at the desired value for the impedance of the load, ZL and to arrive at the target frequency. The algorithm implemented by the match network 104 to accomplish this result will be clearer with reference to examples that follow.

Because an impedance of the load, ZL tends to vary during processing of a workpiece (e.g., a substrate), the element controller 122 may operate on an ongoing basis to adjust the variable reactance section 120 to change its impedance to compensate for fluctuations in the impedance of the dynamic load.

In some variations, a communication link 126 communicatively couples the generator 102 and the match network 104 to enable informational and/or control signals to be sent between the generator 102 and the match network 104. But many implementations do not require the communication link 126, and it should be recognized that in these implementations the match network 104 may operate substantially independent of the generator 102. The specific embodiment of the match network 104 in FIG. 1 (in which the element controller 122 and the measurement section 124 are within the internal controller 119 of the match network 104) may be beneficial for one or more reasons. For example, the internal controller 119 of the match network 104 may have access to internal parameters of the match network 104 that the external controller 107 (or other external controllers) does not have access to. As another example, the internal controller 119 is in closer proximity to the sensors 116, 118; thus, data from the sensors 116, 118 may be received and processed relatively quickly. In addition, the components of the internal controller 119 may be realized on the same printed circuit board or even the same chip (as a system on a chip); thus, very fast bus communications (without the need to translate to another communication protocol, such as a local area network protocol) may be carried out between the components of some embodiments of the internal controller 119.

But in variations of the embodiment depicted in FIG. 1, it may be beneficial to distribute one or more of the components of the match network 104 and/or generator 102, so other configurations are certainly contemplated. For example, one or both of the input sensor 116 and output sensor 118 may be located outside of the match network 104. As another example, the input sensor 116 may reside within the generator 102 and the generator 102 may provide a signal indicative of electrical parameters at the output of the generator 102 to the measurement section 124. Moreover, one or more of the components of the internal controller 119 (e.g., one or more of the element controller 122 and measurement section 124 may be located apart from the match network 104).

For example, it is contemplated that one or more components of the internal controller 119 may be located remotely from the match network 104 and may be coupled to the match network 104, the generator 102, or the external controller 107 by a network connection. It is also contemplated that the frequency-tuning subsystem 103 may be realized, at least in part in the external controller 107. In many instances, operators of plasma processing systems (such as the system depicted in FIG. 1) may prefer to utilize a centralized controller (such as the external controller 107) for convenience, and because the operators may prefer to have control over the logic and algorithms that are utilized in the generator 102 and/or match network 104.

By way of further example, it should also be recognized that the components of the match network 104 are depicted as logical components and that the depicted components may be realized by common constructs (e.g., a common central processing unit and nonvolatile memory) that are closely integrated, or the depicted components may be further distributed. For example, the functionality of the measurement section 124 may be distributed between the input sensor 116 and the output sensor 118 so that signals output from the input sensor 116 and/or output sensor 118 are digital signals that have been processed and digitalized in close connection with the sensors 116, 118, which enables the element controller 122 to directly receive processed signals from the sensors 116, 118.

The specific examples of the distribution of the depicted functions are not intended to be limiting because it is certainly contemplated that various alternatives may be utilized depending upon the type of hardware that is selected and the extent to which software (e.g., embedded software) is utilized.

The element controller 122 may be configured to obtain an input impedance at the input of the match network 104. The input impedance is also referred to herein as a value of the impedance of the load, ZL, presented to the generator 102. As those of ordinary skill in the art will appreciate, the input sensor 116 may provide the necessary measurements of power-related parameters such as voltage, current, phase between the voltage and current, forward power, and reflected power, which may be used to calculate input impedance.

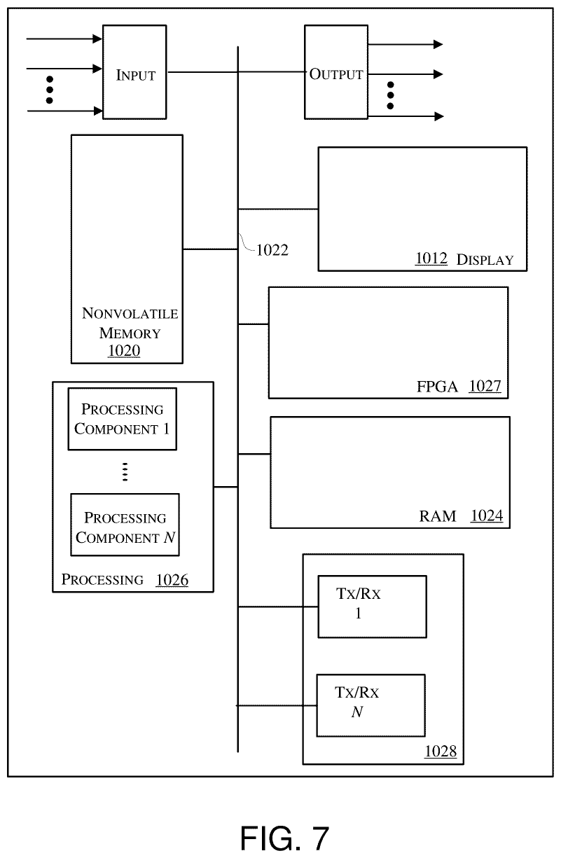

The methods described in connection with the embodiments disclosed herein may be embodied directly in hardware, in processor executable instructions encoded in non-transitory machine readable medium, or as a combination of the two. Referring to FIG. 7 for example, shown is a block diagram depicting physical components that may be utilized to realize one or more of the frequency-tuning subsystem 103, element controller 107, and/or internal controller 119. As shown, in this embodiment a display portion 1012 and nonvolatile memory 1020 are coupled to a bus 1022 that is also coupled to random access memory (“RAM”) 1024, a processing portion (which includes N processing components) 1026, a field programmable gate array (FPGA) 1027, and a transceiver component 1028 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

Display portion 1012 generally operates to provide a user interface for a user, and in several implementations, the display is realized by a touchscreen display. For example, display portion 1012 can be used to control and interact with internal controller 119 in connection with characterizing a dynamic load to produce an associated impedance trajectory. The user interface may also be used to enable an operator to select particular power levels, frequencies, and pulse parameters for the generator 102. In general, the nonvolatile memory 1020 is non-transitory memory that functions to store (e.g., persistently store) data and machine readable (e.g., processor readable and executable) code (including executable code that is associated with effectuating the methods described herein). In some embodiments, for example, the nonvolatile memory 1020 includes bootloader code, operating system code, file system code, and non-transitory processor-executable code to facilitate the execution of the methods (e.g., the methods described with reference to FIG. 4) described herein.

In many implementations, the nonvolatile memory 1020 is realized by flash memory (e.g., NAND or ONENAND memory), but it is contemplated that other memory types may be utilized as well. Although it may be possible to execute the code from the nonvolatile memory 1020, the executable code in the nonvolatile memory is typically loaded into RAM 1024 and executed by one or more of the N processing components in the processing portion 1026.

In operation, the N processing components in connection with RAM 1024 may generally operate to execute the instructions stored in nonvolatile memory 1020 to realize the functionality of frequency-tuning subsystem 103 and element controller 122. For example, non-transitory processor-executable instructions to effectuate the methods described herein may be persistently stored in nonvolatile memory 1020 and executed by the N processing components in connection with RAM 1024. As one of ordinary skill in the art will appreciate, the processing portion 1026 may include a video processor, digital signal processor (DSP), graphics processing unit (GPU), and other processing components.

In addition, or in the alternative, the field programmable gate array (FPGA) 1027 may be configured to effectuate one or more aspects of the methodologies described herein (e.g., the methods described with reference to FIG. 4). For example, non-transitory FPGA-configuration-instructions may be persistently stored in nonvolatile memory 1020 and accessed by the FPGA 1027 (e.g., during boot up) to configure the FPGA 1027 to effectuate the functions of frequency-tuning subsystem 103 and element controller 122, 222.

The input component may operate to receive signals (e.g., from sensors 116, 118) that are indicative of one or more properties of the power that is output by the generator 102 and that characterize the dynamic load, Zp. The signals received at the input component may include, for example, voltage, current, forward power, reflected power, and dynamic load impedance. The output component generally operates to provide one or more analog or digital signals to effectuate an operational aspect of the match network 104 and/or generator 102. For example, the output portion may transmit the adjusted frequency to an exciter of the generator 102 during frequency tuning. The output may also be used to control a positions of the first variable reactive component 113, the second variable reactive component 115, and the third variable reactive component 117.

The depicted transceiver component 1028 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A match network comprising:
an input;
an output;
a first variable reactive component;
a second variable reactive component;
a third variable reactive component; and
a controller configured to:
control the first variable reactive component and the second variable reactive component to, at least in part, match a load impedance at the output to a source impedance at the input during a first and second states; and
set the third variable reactive component so that frequency sweeping completes tuning during at least one of the states.

2. The match network of claim 1, wherein the controller is configured to control the first and second variable reactive components together to match a load impedance at the output to a source impedance at the input during a first state and set the third variable reactive component so that frequency tuning completes tuning during the second state.

3. The match network of claim 1, wherein the first variable reactive component comprises one or more shunt capacitors, the second variable reactive component comprises one or more series capacitors, and the third variable reactive component comprises one or more shunt capacitors.

4. The match network of claim 1, wherein the first variable reactive component comprises one or more shunt capacitors, the second variable reactive component comprises one or more series capacitors, and the third variable reactive component comprises one or more series capacitors.

5. The match network of claim 1 wherein the third variable reactive component comprises an array of fixed reactive components, wherein each reactive component is switchably engaged and disengaged.

6. The match network of claim 1, wherein:
the variable first reactive component is a shunt capacitance that is controlled by the controller to respond to a resistive component of the load impedance;
the variable second reactive component is a series capacitance that is controlled by the controller to respond to a reactive component of the load impedance; and
the third variable reactive component is controlled achieve a desired impedance trajectory when a frequency of power applied to match changes.

7. The match network of claim 1 comprising:
a measurement section configured to provide an output indicative of an impedance of a dynamic load presented to a generator; and
the controller is configured to control first, second, and third variable reactive components based upon the output indicative of an impedance of a dynamic load.

8. A method comprising:
providing power to a dynamic load impedance;
matching a source impedance to the dynamic load impedance during a first and second impedance states by, at least in part, adjusting a first variable reactive component and a second variable reactive component of a match network; and
setting a third variable reactive component of the match network so that frequency sweeping completes tuning during at least one of the first and second impedance states.

9. The method of claim 8, comprising:
controlling the first and second variable reactive components to match the dynamic load impedance to the source impedance during the first impedance state; and
setting the third variable reactive component so that frequency tuning completes tuning during the second state.

10. The method of claim 8, wherein the first variable reactive component includes a shunt capacitor, the second variable reactive component includes a series capacitor, and the third variable reactive component includes a shunt capacitor.

11. The method of claim 8, wherein the first variable reactive component includes a shunt capacitor, the second variable reactive component includes a series capacitor, and the third variable reactive component includes a series capacitor.

12. The method of claim 8 wherein the third variable reactive component comprises an array of fixed reactive components, wherein each reactive component is switchably engaged and disengaged.

13. The method of claim 8, comprising:
obtaining a measure indicative of an impedance of the load; and
controlling the first, second, and third variable reactive components based upon reflected power.

14. A non-transitory processor-readable medium comprising instructions for matching a source impedance with a dynamic load impedance, for execution by a processor or for configuring a field programmable gate array, the instructions comprising instructions to:
match a source impedance to the dynamic load impedance during a first and second impedance states by, at least in part, adjusting a first variable reactive component and a second variable reactive component of a match network; and
set a third variable reactive component of the match network so that frequency sweeping completes tuning during at least one of the impedance states.

15. The non-transitory processor-readable medium of claim 14, the instructions comprising instructions to:
control the first and second variable reactive components to match the dynamic load impedance to the source impedance during the first impedance state; and
set the third variable reactive component so that frequency tuning completes tuning during the second impedance state.

16. The non-transitory processor-readable medium of claim 14, the instructions comprising instructions to coordinate control of the first, second, and third variable reactive components with frequency tuning of a generator to match the dynamic load impedance to the source impedance during the first impedance state and the second impedance state.
